(19) United States
(12) Patent Application Publication
(10) Pub. No.: US 2009/0072881 A1
(43) Pub. Date: Mar. 19, 2009

(54) SYSTEM USING AN ANALOG RECEPTOR FOR PASSAGE OF DIGITAL SIGNALS

(75) Inventor: Siew Ling LOKE, Singapore (SG)

Correspondence Address: CREATIVE LABS, INC.;LEGAL DEPARTMENT, 1901 MCCARTHY BLVD, MILPITAS, CA, 95035, US

(73) Assignee: CREATIVE TECHNOLOGY LTD, Singapore (SG)

(21) Appl. No.: 11/854,769

(22) Filed: Sep. 13, 2007

(51) Int. Cl. H03K 17/00

(52) U.S. Cl. 327/415

(57) ABSTRACT

There is provided a system using an analog receptor for passage of signals (either input or output of signals). The system includes a signal switch device coupled to the analog receptor; and a microcontroller controlling the signal switch device, the microcontroller being for the control of the signal switch device when a determination of a type of input signal through the analog receptor is received by the microcontroller. It is advantageous that the signal switch device allows connection to an analog circuit unless the microcontroller causes the signal switch device to divert digital signals input through the analog receptor to the microcontroller. The system may be used in an apparatus such as, for example, a media player docking station, a media player, a PDA, a portable games console, and a mobile phone. It is preferable that the analog circuit may be selected from for example, an operational amplifier, an analog-to-digital convertor, or a digital-to-analog convertor. It is preferable that the system is connectable to a PC.

### FIELD OF INVENTION

This invention relates to a system which allows passage of digital signals through an analog receptor.

### BACKGROUND

Consumer electronics is an area where rapid development and continual product renewal is essential to keep up with the ever changing tastes of consumers. Nowadays, it is common for many products to be engineered in a manner which allows the product to be enhanced (using firmware updates) or allows rectification of software “bugs” (using firmware patches) throughout its life cycle as the products are often rushed to the market before every single problem has been resolved.

A digital connector is usually incorporated in a product so that firmware in the form of digital data may be passed into a microcontroller of the product for subsequent enhancement or rectification of the product. In view of current trends, consumers now generally prefer products with small and slim form factors. As a result of the need to meet consumers' tastes/expectations, manufacturers of consumer goods constantly have to overcome problems in relation to space constraints on the products.

Generally, when space constraints lead to non-inclusion of a digital connector in the product, the digital signals will likely be routed via a header on a printed circuit board of the product. This causes problems as a casing of the product would need to be opened up to enable uploading of digital signals (firmware) to take place. The casing of the product may be damaged as a result of this process. These inconveniences in relation to uploading of firmware and damage to the casing would be distressing to the consumers.

It would be preferable if digital signals could be input into the products without having to impose penalties in relation to space utilization and form factor for the product.

### SUMMARY

There is provided a system using an analog receptor for passage of signals (either input or output of signals). The system includes a signal switch device coupled to the analog receptor; and a microcontroller controlling the signal switch device, the microcontroller being for the control of the signal switch device when a determination of a type of input signal through the analog receptor is received by the microcontroller. It is advantageous that the signal switch device allows connection to an analog circuit unless the microcontroller causes the signal switch device to divert digital signals input through the analog receptor to the microcontroller. The system may be used in an apparatus such as, for example, a media player docking station, a media player, a PDA, a portable games console, and a mobile phone. It is preferable that the analog circuit may be selected from, for example an operational amplifier, a digital-to-analog convertor, an analog-to-digital convertor and so forth. It is preferable that the system is connectable to a PC.

It is preferable that the analog receptor is selected from either a stereo jack or a multi-pole jack. The analog receptor may preferably allow bidirectional passage of signals. The analog receptor may be a component which has a primary function for either operability or usability of the apparatus.

The determination of a type of input signal through the analog receptor may be done using a switch coupled with the microcontroller. Preferably, the switch has two states of “analog” and “digital”. The determination of a type of input signal through the analog receptor may be done either by a user specifying the type of input signal using the switch, or by detection of the input signal by the analog receptor. Alternatively, the determination of a type of input signal through the analog receptor may be done with a user activating an application software at a host, the microcontroller subsequently analysing wave patterns transmitted by the host in response to activation of the application software, the microcontroller being in either a “digital” or “analog” state depending on the type of input signal.

It is preferable that the detection of the input signal by the analog receptor is by analyzing wave patterns of the input signals using the microcontroller. The microcontroller may preferably include non-volatile memory. The microcontroller may also be coupled to a device for data storage.

The digital signals may be in the form of digital files. The digital files may preferably be, for example, firmware, media files, application files, and document files.

### DESCRIPTION OF DRAWINGS

In order that the present invention may be fully understood and readily put into practical effect, there shall now be described by way of non-limitative example only preferred embodiments of the present invention, the description being with reference to the accompanying illustrative drawings.

FIG. 1 shows a schematic diagram of a preferred embodiment of the present invention.

### DESCRIPTION OF PREFERRED EMBODIMENTS

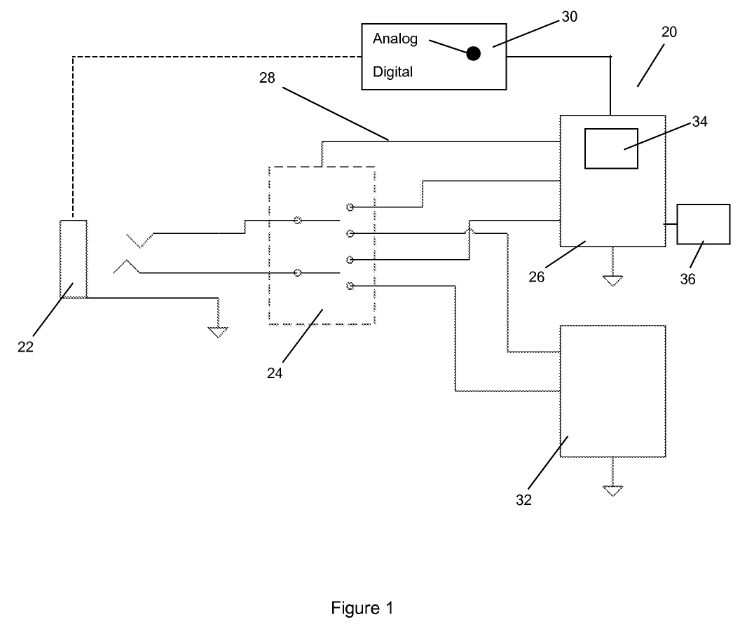

Referring to FIG. 1, there is shown a system 20 using an analog receptor 22 for passage of signals. The signals may either pass into the system 20 or exit from the system 20. The analog receptor 22 may be either a stereo jack or a multi-pole jack. The system 20 may be used in an apparatus such as, for example, a media player docking station, a media player, a PDA, a portable games console, a mobile phone or similar sort of apparatus. It is preferable that the analog receptor 22 is a component which has a primary function relating to either operability or usability of the apparatus. It is also preferable that the analog receptor 22 allows bidirectional passage of signals. As such, signals may pass into the system 20 or out from the system 20 through the analog receptor 22. The system 20 may be used for uploading digital data to the apparatus, the digital data being digital files. The digital files may be, for example, firmware, media files, application files, document files and so forth. The system 20 may be connectable to a host which contains digital data, such as, for example, a PC.

The system 20 may include a signal switch device 24 coupled to the analog receptor 22. The signal switch device 24 may be controlled 28 by a microcontroller 26 of the system 20. The microcontroller 26 controls the signal switch device 24 depending on a determination of a type of input signal through the analog receptor 22. The determination of a type of input signal is through a switch 30 coupled with the microcontroller 26. The switch 30 may have two states, namely, “analog” and “digital”. A user may manually toggle the switch 30 to specify whether the type of input signal is digital or analog. Alternatively, the switch 30 may be coupled directly to the analog receptor 22, with the analog receptor 22 having a facility to automatically detect whether the type of input signal is digital or analog. Detection of the type of input signal at the analog receptor 22 may be from analyzing wave patterns of the input signals using the microcontroller 26. The microcontroller 26 may poll and analyse the input signals at regular intervals to determine the wave patterns of the input signals. The analog receptor 22 may subsequently activate the switch 30 to an appropriate state of either “analog” or “digital”. When the microcontroller 26 receives a signal from the switch 30, the signal switch device 24 may then be consequently controlled 28 by the microcontroller 26. The switch 30 may be configured in a manner such that the signal is only transmitted by the switch 30 when the switch 30 is in the “digital” state.

When the state of the switch 30 is in the “digital” state, the microcontroller 26 may instruct 28 the signal switch device 24 to divert digital signals input through the analog receptor 22 to the microcontroller 26. The microcontroller 26 may include non-volatile memory 34 that may be used for storing the digital signals input through the analog receptor 22. Generally, the state of the switch 30 may be in the “analog” state (by default) such that the signal switch device 24 allows connection of the analog receptor 22 to an analog circuit 32 unless there is input of digital signals into the system 20 through the analog receptor 22. The analog circuit 32 may include, for example, an operational amplifier, an analog-to-digital convertor or a digital-to-analog convertor.

In an alternative embodiment, the determination of the type of input signal may be done with user intervention without a need for the switch 30. In the alternative embodiment, the user may activate an application software at the host prior to activation of the system 20. The microcontroller 26 may subsequently analyse the wave patterns transmitted by the host in response to activation of the application software. If the wave patterns match digital patterns, the microcontroller 26 may enter into the “digital” state. The microcontroller 26 remains in the “analog” state if the wave patterns do not match digital patterns.

In the alternative embodiment, when the microcontroller 26 is in a “digital” state, the microcontroller 26 may instruct 28 the signal switch device 24 to divert digital signals input through the analog receptor 22 to the microcontroller 26. The microcontroller 26 may include non-volatile memory 34 that may be used for storing the digital signals input through the analog receptor 22. Generally, the state of the microcontroller 26 may be in the “analog” state (by default) such that the signal switch device 24 allows connection of the analog receptor 22 to an analog circuit 32 unless there is input of digital signals into the system 20 through the analog receptor 22. The analog circuit 32 may include, for example, an operational amplifier, an analog-to-digital convertor or a digital-to-analog convertor.

The microcontroller 26 may also be coupled to a device for data storage 36. The device may be a hard-disk or flash memory. In such an embodiment, the input of digital signals into the system 20 through the analog receptor 22 may also be stored in the device for data storage 36.

Whilst there has been described in the foregoing description preferred embodiments of the present invention, it will be understood by those skilled in the technology concerned that many variations or modifications in details of design or construction may be made without departing from the present invention.

1. A system using an analog receptor for passage of signals, the system including:
a signal switch device coupled to the analog receptor; and
a microcontroller controlling the signal switch device, the microcontroller being for the control of the signal switch device when a determination of a type of input signal through the analog receptor is received by the microcontroller;
wherein the signal switch device allows connection to an analog circuit unless the microcontroller causes the signal switch device to divert digital signals input through the analog receptor to the microcontroller.

2. The system of claim 1, wherein the analog receptor is selected from either a stereo jack or a multi-pole jack.

3. The system of claim 1, wherein the analog receptor allows bi-directional passage of signals.

4. The system of claim 1, wherein the determination of a type of input signal through the analog receptor is done using a switch coupled with the microcontroller.

5. The system of claim 4, wherein the switch has two states of “analog” and “digital”.

6. The system of claim 4, wherein the determination of a type of input signal through the analog receptor is done either by a user specifying the type of input signal using the switch or by detection of the input signal by the analog receptor.

7. The system of claim 6, wherein the detection of the input signal by the analog receptor is by analyzing wave patterns of the input signals using the microcontroller.

8. The system of claim 1, wherein the digital signals are in the form of digital files.

9. The system of claim 8, wherein the digital files are selected from the group consisting of: firmware, media files, application files, and document files.

10. The system of claim 1 being used in an apparatus selected from a group consisting of: a media player docking station, a media player, a PDA, a portable games console, and a mobile phone.

11. The system of claim 10, wherein the analog receptor is a component which has a primary function for either operability or usability of the apparatus.

12. The system of claim 1, wherein the analog circuit is selected from the group consisting of: an operational amplifier, an analog-to-digital convertor and a digital-to-analog convertor.

13. The system of claim 1, wherein the microcontroller includes non-volatile memory.

14. The system of claim 1, further including a device for data storage that is coupled to the microcontroller.

15. The system of claim 1, wherein the system is connectable to a PC.

16. The system of claim 1, wherein the determination of a type of input signal through the analog receptor is done with a user activating an application software at a host, the microcontroller subsequently analysing wave patterns transmitted by the host in response to activation of the application software, the microcontroller being in either a “digital” or “analog” state depending on the type of input signal.
